(19) United States
(12) Patent Application Publication
(10) Pub. No.: US 2025/0309155 A1
(43) Pub. Date: Oct. 2, 2025

(54) EMBEDDED CAPACITOR PACKAGE SUBSTRATE

(71) Applicant: Rivian IP Holdings, LLC, Irvine, CA (US)

(72) Inventors: Mengzhi PANG, Cupertino, CA (US); Mukund Tejkumar CHAVAN, Fremont, CA (US); Jiangong WEI, San Diego, CA (US); Shiji PAN, Irvine, CA (US); Zijie CAI, Irvine, CA (US); Marcus Hwai Yik TAN, Union City, CA (US)

(21) Appl. No.: 19/096,316

(22) Filed: Mar. 31, 2025

Related U.S. Application Data
(60) Provisional application No. 63/572,836, filed on Apr. 1, 2024.

(51) Int. Cl. H01L 23/66; H01L 23/498

(52) U.S. Cl. CPC H01L 23/66; H01L 23/49816

(57) ABSTRACT

Aspects of the disclosure relate to embedded capacitor package substrate. One or more high frequency capacitors (such as silicon based capacitors) may be embedded in a substrate core.

### CROSS-REFERENCE TO RELATED APPLICATIONS

The present application claims the benefit of U.S. Provisional Application No. 63/572,836 entitled, “EMBEDDED CAPACITOR PACKAGE SUBSTRATE”, filed Apr. 1, 2024, the entirety of which is incorporated herein for reference.

### INTRODUCTION

A capacitor is a passive electronic component with the ability to store an electrical charge. It consists of two conductive plates separated by an insulating material known as the dielectric. When a voltage is applied across the capacitor, it stores energy in its electric field, and when the voltage is removed, it releases that stored energy.

Aspects of the subject technology can help to improve the overall efficiency of circuits or other electronic components.

### SUMMARY

The present description is generally directed to an embedded capacitor package substrate, which may enhance power delivery of high-performance IPs. Embedding high frequency capacitors (such as silicon-based capacitors) in package substrate may result in suppression of high switching noise, such as a di/dt event, of compute IPs (e.g., autonomous driving artificial intelligence (AI) based IPs). Performance effects may include a boost in frequency for given voltage levels.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an exemplary system of a ball grid array (BGA) package and board.

FIG. 2 illustrates an exemplary graph displaying voltage swings associated with an implementation of a BGA package.

FIG. 3 illustrates an exemplary system of an embedded capacitor package and board.

FIG. 4 illustrates an exemplary method for an embedded capacitor package.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

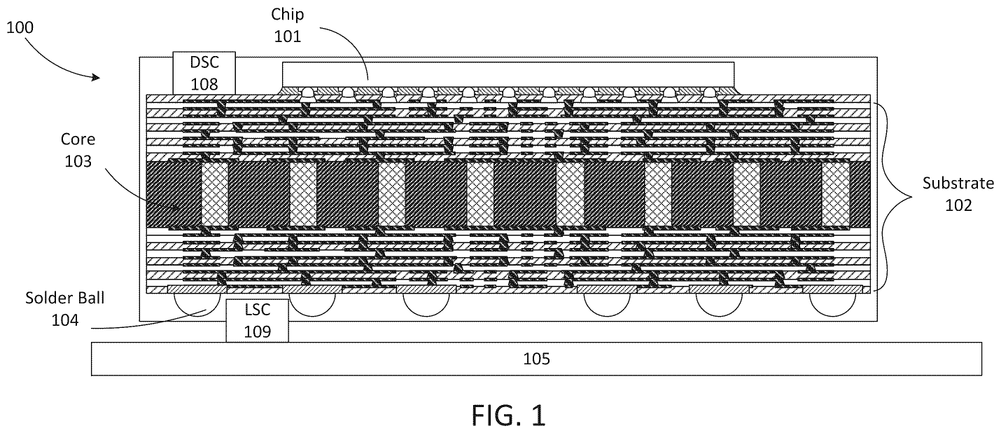

FIG. 1 illustrates an exemplary system of an integrated circuit package and board. Ball grid array (BGA) package 100 may include chip 101, substrate 102, and solder balls 104. Substrate 102 may include core 103. Substrate 102 may be attached to chip 101 and solder balls 104. Solder balls 104 may be soldered to board 105 to create a connection. One or more capacitors (e.g., die-side capacitor (DSC) 108 or land-side capacitor (LSC) 109) may be included and may have the effect of reducing noise, reducing impedance, or maintaining a constant voltage under various operating frequencies. As shown in FIG. 1, DSC 108 is a capacitor that may be attached to the integrated circuit substrate 102 on the die side adjacent to the die (e.g., chip 101). LSC 109 is a capacitor that is attached to the integrated circuit substrate on the land side, and its form factor may be based on the substrate size and the collapsed height of solder balls 104. DSC 108 or LSC 109 may be used in different integrated circuit package implementations.

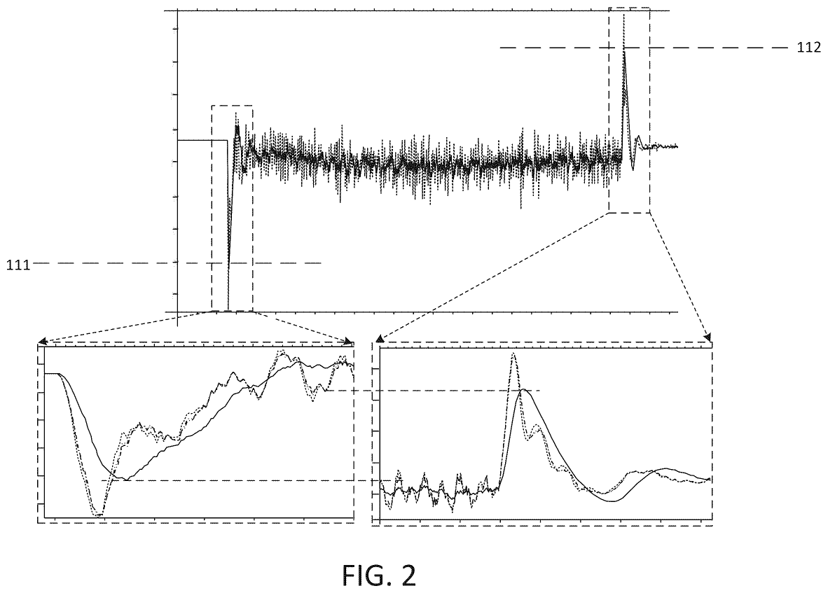

FIG. 2 illustrates an exemplary graph displaying voltage swings associated with an implementation of an integrated circuit package (e.g., BGA package 100). In example, with reference to threshold 111, this magnitude of voltage may lead to functional failure when the minimal voltage falls below the minimum operating voltage band (e.g., threshold 111). In another example, with reference to threshold 112, this magnitude of voltage may lead to reliability failure when the maximum voltage exceeds the maximum operating voltage band (e.g., upper threshold 112).

With continued reference to FIG. 2, voltage swings may have significant dependence on di/dt (e.g., current ramping up and ramping down profile). The voltage swing may depend on how fast supplying current ramps up and down (e.g., di/dt), in which the faster di/dt, the worse voltage swing. The disclosed subject matter provides for ways to suppress high frequency noise associated with faster di/dt, and therefore may improve performance of the integrated circuit package, which may be implemented in an advanced driver assistance system (ADAS).

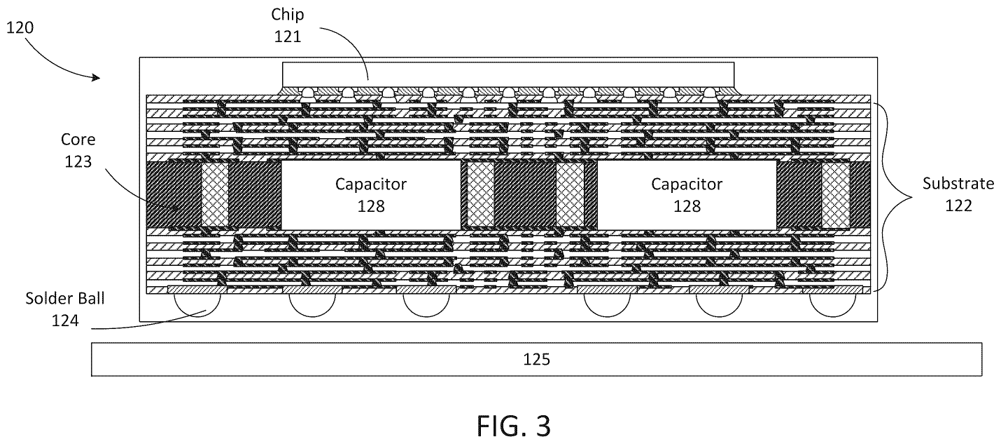

FIG. 3 illustrates an exemplary system of an embedded capacitor package 120 and board 125. Embedded capacitor package 120 may include chip 121, substrate 122, and solder balls 124. Substrate 122 may include core 123. Substrate 122 may be attached to chip 121 and solder balls 124. Solder balls 124 may be soldered to board 125 to create a connection. One or more capacitors (e.g., core capacitor 128) may be included and may have the effect of reducing noise, reducing impedance, or maintaining a constant voltage under various operating frequencies. Core capacitor 128 may be located directly under the computing process shadow of chip 121.

Embedded capacitor package 120, as shown in FIG. 3, may provide, when compared to other packages, a relatively low inductance path from decoupling capacitors to computing processor. The use of embedded capacitor package 120 may result in significant reduction of mounting inductance (e.g., from approximately 100 pico henry to less than 10 pico henries) at a higher decoupling frequency range (e.g., from approximately 10-20 MHz of conventional implementation to approximately 70-80 MHz in an embedded silicon capacitor implementation). The integration of one or more silicon capacitors into the package substrate may help suppress voltage swings by approximately 30-40% across a range of frequency bands (e.g., in a comparison of fully optimized power distribution network (PDN) solution of conventional package and the disclosed embedded capacitor implementation).

Core capacitors 128 may be high frequency decoupling capacitors, such as silicon capacitors. Experimentation has shown that silicon capacitors maintain their performance consistently across a wide temperature range, making them suitable for applications operating in extreme conditions where reliability is crucial (e.g., automotive ADAS context). Silicon capacitors may be constructed using a silicon wafer as the dielectric material and may be suited for high-frequency applications due to low parasitic effects and minimal losses.

While electrical benefits have been demonstrated through design feasibility herein, issues regarding manufacturability, assembly, or automotive grade qualification may be further addressed. Disclosed herein are examples of how to realize PDN benefit by manufacturability of embedded capacitor substrate, assembly with SoC silicon, or automotive grade qualification. A robust process to embed a capacitor into an organic substrate may include the following issues: 1). thermal expansion and 2) filling gaps in the core substrate. With reference to thermal expansion issues, there may be a thermal expansion coefficient mismatch between silicon (e.g., approximately 3-4 ppm/° C.) vs organic substrate core (e.g., approximately 10 ppm/° C.) that may create mechanical stress which may lead to package warpage or stress driven failure (e.g., delamination or cracking).

With reference to gaps in the core substrate, the aspect ratio to fill a gap between silicon capacitor and organic substrate core presents a challenge. In the process flow, initially a cavity may be created within the substrate core, then a silicon capacitor may be placed inside the cavity. Subsequently, there may be a narrow gap in between (e.g., approximately 50-100 um) that may need to be filled without void. If the gap is not filled, there may be a manufacturing concern associated with a subsequent substrate lamination build up layer or a reliability issue.

To address the aforementioned issues, a lower coefficient of thermal expansion (CTE) substrate core (e.g., approximately 5-7 ppm/° C.) may be selected in order to match better (e.g., approximately similar) with the silicon capacitor (e.g., capacitor 128) so as to suppress mechanical stress. The similar CTE of the substrate core and silicon substrate may be addressed in conjunction with core thickness and gap filling material with high flowability. The disclosed material or process combination has been identified for feasible manufacturing of embedded silicon capacitor substrate. The thickness of the silicon capacitor may be comparable to the core thickness in this embedded process. Comparable may be a consideration that silicon capacitor thickness and core thickness are similar, which may not be exactly the same (e.g., approximately 100 micrometer thickness difference). After creating a cavity in the core and placing the silicon capacitor inside, an air gap may form between the silicon capacitor and the core cavity. To address this, high flowability gap filling materials may be utilized to fill the air gap. These materials are capable of filling high aspect ratio gaps between the silicon capacitor side wall and the core cavity side wall. The high flowability materials may be dielectric materials that flow into the gap when subjected to heat and lamination processes.

Another aspect to consider is package structural integrity when SoC silicon is flip chip attached to the substrate with the application of a thermal lid as final component. An analysis was conducted to assess mechanical stress in relation to the package stackup. Through this sensitivity study, the robustness of various package structures was evaluated and ranked, leading to the selection of plan-of-record options for the embedded capacitor substrate flip-chip package. In this context, the package structure refers to the stackup, which includes elements such as the lid, die, and substrate. The robustness of the package indicates that the stress generated due to coefficient of thermal expansion (CTE) mismatches among different materials in the stackup meets manufacturing and qualification requirements. If the stress level exceeds these criteria, field failures may occur.

A third aspect is to evaluate automotive grade qualification of the embedded capacitor package. Under the Automotive Electronics Council (AEC) Q100 grade 2 requirements of ADAS chip packaging, the intrinsic risk of qualification is low for the down-selected package structure. This, combined with enhanced defect screening and data retention mechanisms of automotive components (e.g., as documented in Production Part Approval Process (PPAP)), suggests that this embedded capacitor package structure may be able to bring up to mass production for ADAS applications.

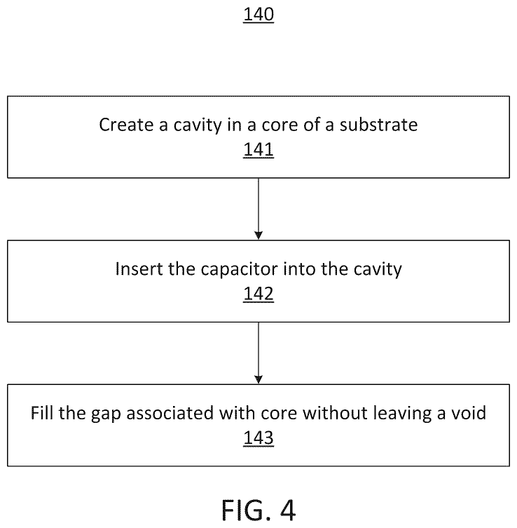

The methods, systems, or apparatuses disclosed herein may be incorporated into electric vehicles or other devices, or may be used for an automatous driving application. FIG. 4 illustrates an example method 140 for an embedded capacitor package as disclosed herein. At step 141, a cavity may be created in a core 123 of a substrate 122. Precision machining or etching techniques may be used to ensure the cavity is of appropriate size and shape to accommodate the capacitor 128.

At step 142, one or more capacitors 128 may be inserted into the cavity of the core 123. The one or more capacitors 128 may include silicon capacitors. The capacitor 128 may be appropriately aligned within the cavity to facilitate the gap-filling process.

At step 143, subsequent to inserting the one or more capacitors 128, one or more gaps associated with the core may be filled without leaving a void therein. This step may assist with structural integrity and performance of the one or more capacitors 128. The filling of the one or more gaps may comprise using a high flowability gap filling material. The high flowability gap filling material may be specially designed to ensure encapsulation of the one or more capacitors 128 within the core.

The method 140 may further include additional considerations. For instance, a core material may be selected having a coefficient of thermal expansion of approximately 5 ppm/° C. to 7 ppm/° C. This selection may minimize thermal stress between the core 123 and the embedded one or more capacitors 128 during temperature fluctuations, which may otherwise lead to reliability issues over time.

Alternatively or additionally, the core material may be selected to have a coefficient of thermal expansion that is approximately equal to the coefficient of thermal expansion of the one or more capacitors 128. This matching of thermal expansion coefficients may reduce thermal stresses at the interface between the one or more capacitors 128 and the core material.

Embedding capacitors directly within the substrate core, may allow for shorter electrical paths, reduced parasitic effects, and improved overall system performance. This technique may be particularly useful with high-frequency applications.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term “include”, “have”, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, or systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects. All structural and functional equivalents to the elements of the various aspects

described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f), unless the element is expressly recited using the phrase “means for” or, in the case of a method claim, the element is recited using the phrase “step for”.

Those of skill in the art would appreciate that the various illustrative blocks, modules, elements, components, methods, and algorithms described herein may be implemented as hardware, electronic hardware, computer software, or combinations thereof. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

An integrated circuit package, method of embedding a capacitor, and electronic device are disclosed herein. An integrated circuit package is disclosed herein. The integrated circuit package may include a die; a substrate, wherein the die is disposed above the substrate; a core within the substrate; and one or more capacitors positioned within the core of the substrate. The one or more capacitors may comprise a silicon capacitor. The integrated circuit package may be integrated into an electric vehicle. The core of the substrate may have a coefficient of thermal expansion of approximately 5 ppm/° C. to 7 ppm/° C. The integrated circuit package may be a ball grid array package. The core may have a coefficient of thermal expansion that is approximately equal to a coefficient of thermal expansion of the one or more capacitors. The integrated circuit package may further include a high flowability gap filling material surrounding the one or more capacitors within the core. All combinations (including the removal or addition of elements) in this paragraph and previous paragraphs are contemplated in a manner that is consistent with the other portions of the detailed description.

A method of embedding a capacitor is also disclosed. The method may include creating a cavity in a core of a substrate; inserting one or more capacitors into the cavity of the core; and filling, subsequent to inserting the one or more capacitors, one or more gaps associated with the core without leaving a void therein. The filling of the one or more gaps may include using a high flowability gap filling material. The method may further include selecting a core material having a coefficient of thermal expansion of approximately 5 ppm/° C. to 7 ppm/° C. or selecting the core material having a coefficient of thermal expansion that is approximately equal to a coefficient of thermal expansion of the one or more capacitors. The substrate may be part of an integrated circuit package, which may be integrated into an electric vehicle or may be a ball grid array package. All combinations (including the removal or addition of elements) in this paragraph and previous paragraphs are contemplated in a manner that is consistent with the other portions of the detailed description.

An electronic device is further disclosed. The electronic device may include a circuit board and an integrated circuit package coupled with the circuit board. The integrated circuit package may include a die; a substrate, wherein the die is disposed above the substrate; a core within the substrate; and one or more capacitors positioned within the core of the substrate. The one or more capacitors may be positioned under a computing processor shadow of the die. The integrated circuit package may be integrated into an autonomous driving system. All combinations (including the removal or addition of elements) in this paragraph and previous paragraphs are contemplated in a manner that is consistent with the other portions of the detailed description.

What is claimed is:

1. An integrated circuit package comprising:
a die;
a substrate, wherein the die is disposed above the substrate;
a core within the substrate; and
one or more capacitors positioned within the core of the substrate.

2. The integrated circuit package of claim 1, wherein the one or more capacitors comprise a silicon capacitor.

3. The integrated circuit package of claim 1, wherein the integrated circuit package is integrated into an electric vehicle.

4. The integrated circuit package of claim 1, wherein the core of the substrate comprises a coefficient of thermal expansion of approximately 5 ppm/° C. to 7 ppm/° C.

5. The integrated circuit package of claim 1, wherein the integrated circuit package is a ball grid array package.

6. The integrated circuit package of claim 1, wherein the core has a coefficient of thermal expansion that is approximately equal to a coefficient of thermal expansion of the one or more capacitors.

7. The integrated circuit package of claim 1, further comprising a high flowability gap filling material surrounding the one or more capacitors within the core.

8. A method of embedding a capacitor, the method comprising:
creating a cavity in a core of a substrate;
inserting one or more capacitors into the cavity of the core; and
filling, subsequent to inserting the one or more capacitors, one or more gaps associated with the core without leaving a void therein.

9. The method of claim 8, wherein the one or more capacitors comprise a silicon capacitor.

10. The method of claim 8, wherein the filling of the one or more gaps comprises using a high flowability gap filling material.

11. The method of claim 10, further comprising selecting a core material having a coefficient of thermal expansion of approximately 5 ppm/° C. to 7 ppm/° C.

12. The method of claim 8, further comprising selecting core material having a coefficient of thermal expansion that is approximately equal to a coefficient of thermal expansion of the one or more capacitors.

13. The method of claim 8, wherein the substrate is part of an integrated circuit package.

14. The method of claim 13, wherein the integrated circuit package is integrated into an electric vehicle.

15. The method of claim 13, wherein the integrated circuit package is a ball grid array package.

16. An electronic device comprising:
a circuit board; and
an integrated circuit package coupled with the circuit board, the integrated circuit package comprising:
a die;
a substrate, wherein the die is disposed above the substrate;
a core within the substrate; and
one or more capacitors positioned within the core of the substrate.

17. The electronic device of claim 16, wherein the one or more capacitors comprise a silicon capacitor.

18. The electronic device of claim 16, wherein the one or more capacitors are positioned under a computing processor shadow of the die.

19. The electronic device of claim 16, wherein the integrated circuit package is integrated into an autonomous driving system.

20. The electronic device of claim 16, wherein the integrated circuit package is a ball grid array package.
